(19) United States
(12) Patent Application Publication
(10) Pub. No.: US 2005/0254208 A1
(43) Pub. Date: Nov. 17, 2005

(54) Air flow direction neutral heat transfer device

(76) Inventors: Christian L. Belady, McKinney, TX (US); Roy M. Zeighami, McKinney, TX (US); Joshua D. Moody, Portland, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/847,274

(22) Filed: May 17, 2004

(51) Int. Cl. H05K 7/20

(52) U.S. Cl. 361/690

(57) ABSTRACT

In one embodiment, there is shown a heat transfer device having at least one ultra-dense heat sink, where the heat sink is maintained in a position to be air flow direction neutral. In another embodiment, there is shown a method of conducting heat away from an electronic device wherein the electronic device is constructed on a circuit board, the method comprises placing a plurality of heat transfer devices in heat transfer relationship with the electronic device and passing air through the heat transfer devices in at least one air flow direction.

### FIELD OF THE INVENTION

This invention relates to heat transfer devices and more particularly to such devices for use with multi-directional air flow.

### DESCRIPTION OF RELATED ART

Electronic circuits tend to generate heat which then must be removed from the circuit for proper operation. A heat sink closely positioned with respect to the electronic circuit is often employed to assist in heat removal. Often, the heat sink size is limited by the available space on a circuit board or other circuit mounting structure.

Heat sinks operate by removing the heat generated by the electronic circuit. This removal process is aided by allowing the heat from the circuit to pass into “cooling fins” (sometimes using a heat transfer gel) and then passing air across the surface of the fins to transport the heat from the fins to another location. This other location is usually outside of the housing containing the heat generating circuit. Typically, a particular heat sink functions with air moving in one direction with respect to the orientation of the heat sink cooling fins. Thus, in order to avoid the necessity of designing different heat sink configurations for different air flow directional movements, designers have attempted to design heat sinks that are air flow neutral such that they can function with air that can flow from more than one direction.

Some heat sinks have been designed with their cooling fins cross-cut so that the air can pass both parallel and horizontal to the fins. These arrangements have not been particularly effective. Other heat sinks have been designed using pin fins which allow the air to move past the pins in any direction. These pin fins allow air to flow in multiple directions, but for the equivalent thermal performance of plate fins, the pin fins require higher pressure drop.

### BRIEF SUMMARY OF THE INVENTION

In one embodiment, there is shown a heat transfer device having at least one ultra-dense heat sink where the heat sink is maintained in a position to be air flow direction neutral. In another embodiment, there is shown a method of conducting heat away from an electronic device wherein the electronic device is constructed on a circuit board, the method comprises placing a plurality of heat transfer devices in heat transfer relationship with the electronic device and passing air through the heat transfer devices in at least one air flow direction.

### BRIEF DESCRIPTION OF THE DRAWINGS

FIG. 1 illustrates one embodiment of an ultra-dense heat sink;

FIG. 2 illustrates the heat sink of FIG. 1 superimposed on the footprint of an electronic circuit;

FIGS. 3A, 3B, 3C, 3D show embodiments of several ultra-dense devices using heat sinks positioned with respect to an electronic circuit; and

FIGS. 4, 5, 6, 7 and 8 illustrate embodiments of ultra-dense heat sinks.

### DETAILED DESCRIPTION

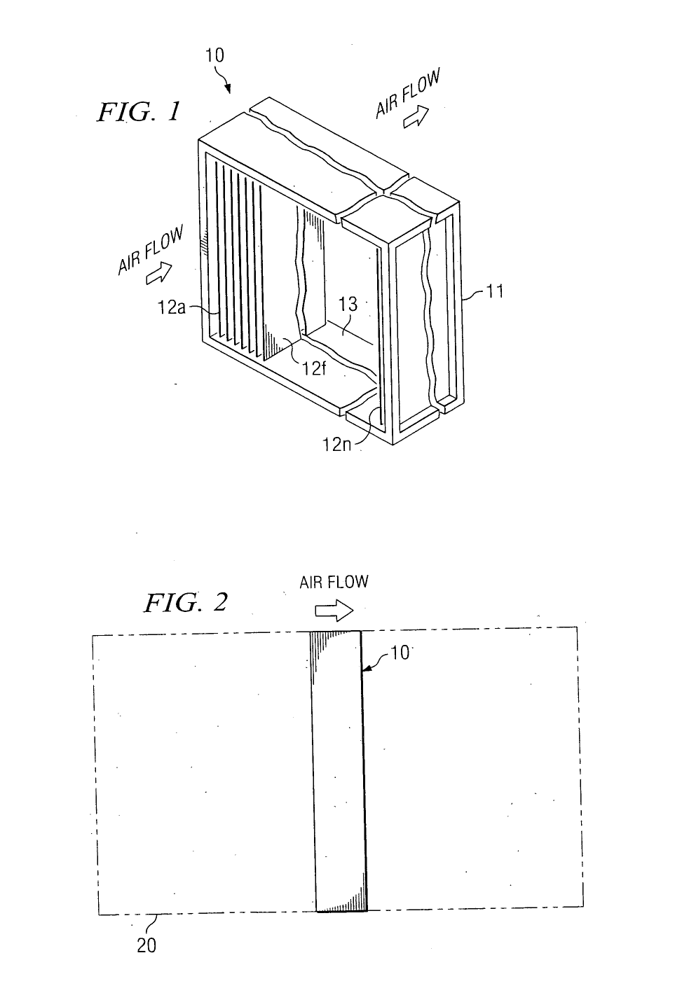

FIG. 1 illustrates one embodiment 10 of an ultra-dense heat sink having frame 11 (optional) and a series of heat transfer elements 12a and 12n, and base 13 for contact with a device from which heat is to be removed. Heat transfer elements are, in this embodiment, plate fins. Air is shown flowing from front to back. Elements 12a-12n are densely packed on the order of at least 30 fins (elements) per inch with element spacings on the order of a few hundred microns. (The illustration is not scale) Proper heat transfer is achieved by managing thermal resistance as a trade off between more cooling area and pressure drop. This trade off is a function of the Reynolds number and, in one embodiment, can follow the principles set forth in U.S. Pat. No. 6,422,307 which patent is hereby incorporated herein. Essentially, the heat transfer co-efficient is increased more than the heat transfer area is decreased. The physical size of heat sink 10 can be designed, if desired, to be no larger than the size of a typical electrical component that it is associated with. As will be discussed herein, this reduced footprint allows denser component possibilities and/or design flexibility within an allocated space. The smaller size also reduces the overall weight of the device by at least fifty percent depending on the materials used in the device, which also would provide cost savings.

FIG. 2 illustrates ultra-dense heat sink 10 superimposed on footprint 20 of a typical electronic circuit. Footprint 20 is the space allocated in our example for conventionally designed heatsinks. Note that in some cases the original sized heat sink could even be larger than the device to be cooled. Thus, since a heat sink using the concepts discussed herein can be made much smaller, it would be a design choice as to the exact size. One consideration is that if the heat sink were to be designed too narrow (from top to bottom in FIG. 2) then the air could easily flow around the heat sink because of the high impedance of the heat sink. Thus, as shown in FIG. 2, heat sink 10 is shown covering the full width of footprint 20. Air is shown flowing from left to right. Using ultra-dense heat sink 10, the device has gone from the full dimension of the footprint (as shown by dashed line 20) to a much smaller profile, even though it covers the full width of the footprint. One advantage of using an ultra-dense heat sink is the reduction in weight achieved. In some situations, this weight reduction could be in the range of 80%.

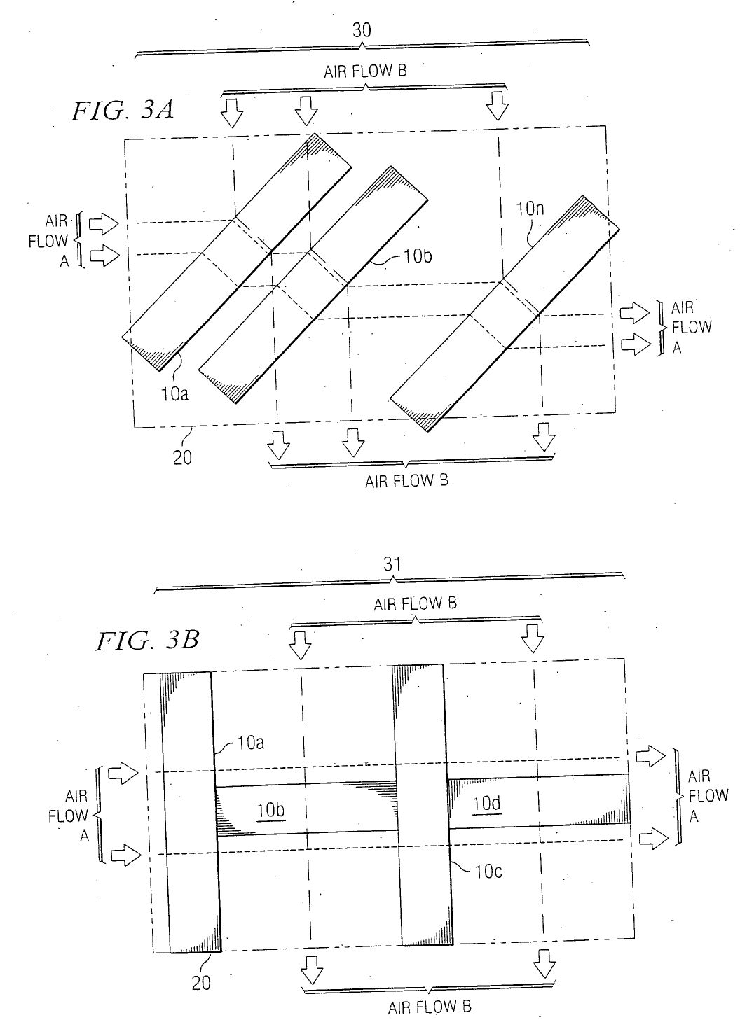

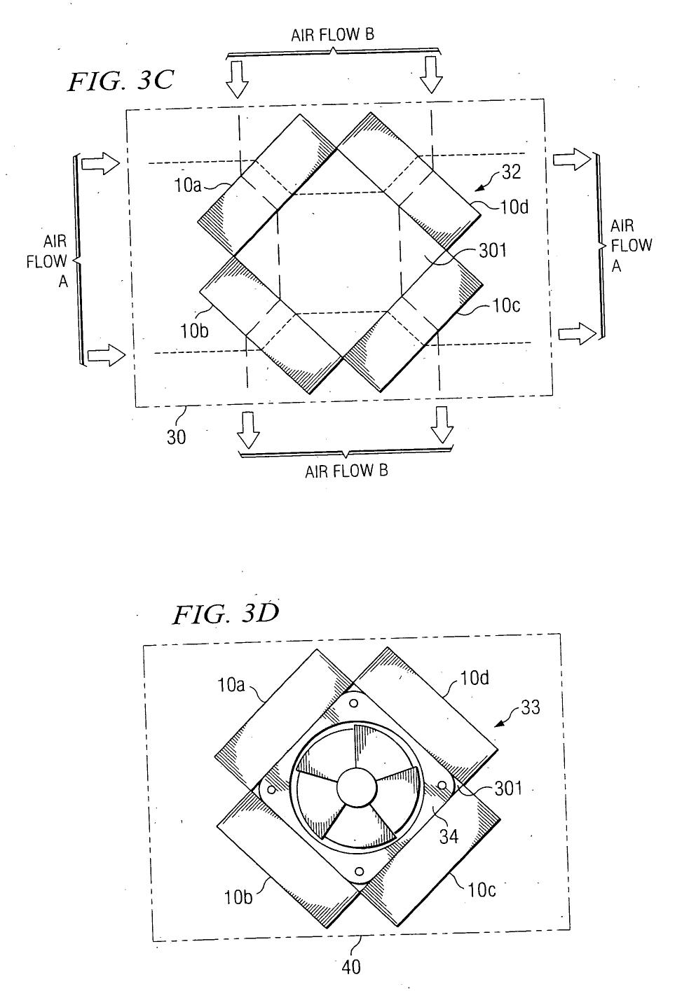

FIG. 3A shows one embodiment of device 30 utilizing a plurality of ultra-dense heat sinks, such as heat sinks 10a to 10n. The heat sinks are tilted, for example, 45 degrees with respect to the air flow so as to accommodate any air flow direction, thereby making device 30 air flow directionally neutral. In the embodiment shown, the air zig zags briefly as it passes through the various heat sinks 10a-10n. The air can flow in direction A (left to right) or in direction B (top to bottom), or both, or reverse therefrom, if desired. Advantage has been taken of the relatively small size of each ultra-dense heat sink 10 to position a plurality of such devices angularly with respect to the anticipated air flow direction. While multiple elements are shown in FIG. 3A, a single element can be positioned at an angle spanning the entire width of space 20 as shown in FIG. 7. One or more or all of heatsinks 10a-10n can be tilted in the opposite direction, if desired.

FIG. 3B illustrates embodiment 31 in which heat sinks 10a and 10c have cooling air moving there through in the A direction. Heat sinks 10b and 10d, which are angularly displaced (in the embodiment shown they are displaced 90 degrees) with respect to heat sinks 10a and 10n, have cooling air moving there through in the B direction. As shown, the heat sinks faced in the A direction form a multi pass heat sink device while those positioned in the B direction form a single pass heat sink device. In the embodiment shown, air flowing in direction A will pass through multiple devices 10, while air flowing in direction B passes through a single device. Note that in FIG. 3A, only four heat sinks are shown, but any number could be used. Accordingly, to prevent air from flowing around the heat sink it may be necessary to duct the air flow tightly. Additional fans are an alternative for solving the high impedance problem.

FIG. 3C illustrates embodiment 32 constructed with a plurality, (in this case four) ultra-dense heat sinks 10a-10d around a central core area 301 to be cooled. Air can flow in both the A and B directions, or in any direction in between, if desired. Note that embodiment 32 can be, if desired a single assembly.

FIG. 3D illustrates embodiment 33 in which an air movement device, such as fan (or blower) 34, is positioned within central (core) space 301. Fan (or blower) 34 can blow air out, or suck air in. Also, the air could be blown upward (out of the page) or, the air could flow in from the top and be blown out radially through heat sinks 10a-10d. A fan would typically be above the core while a blower could be positioned within the core.

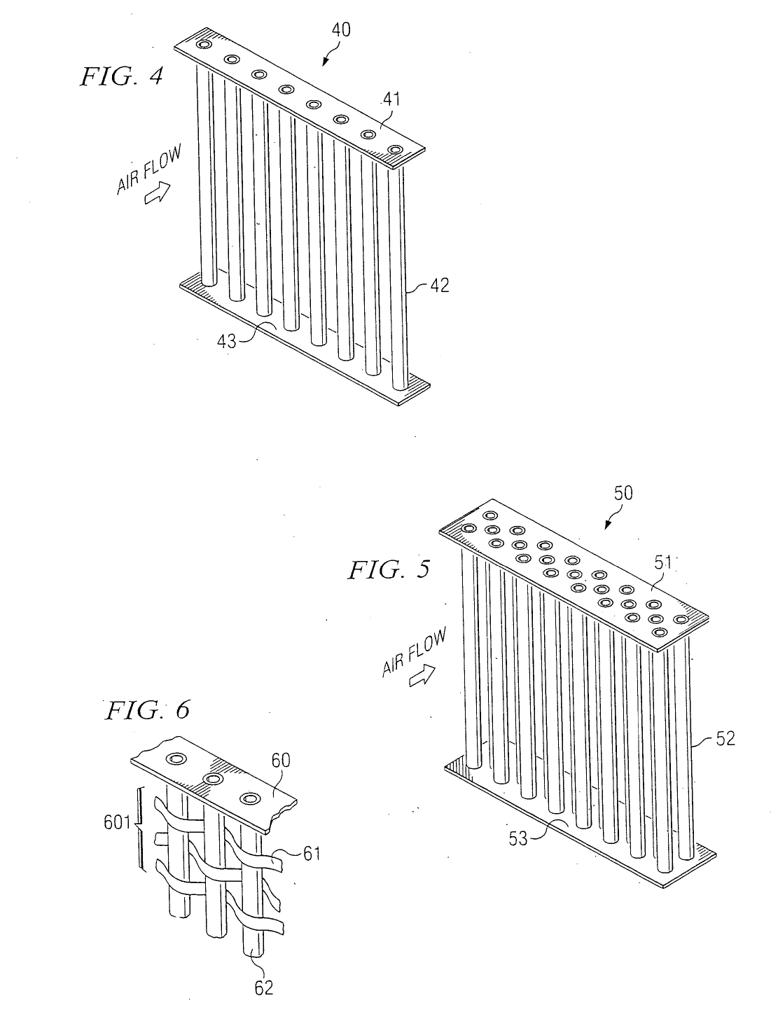

FIG. 4 illustrates embodiment 40 having, for example, carbon nanotubes 42 or fibers, or any other highly conductive material, if desired, could form the nucleus of a covered fin (as shown in FIG. 1) supported by frame top 41 and frame base 43. These elements, nanotubes 42 (or other material) are shown greatly expanded, but would be sized and spaced so that there would be 30 or more fins (tubes) per inch spaced apart in the micron range.

FIG. 5 illustrates embodiment 50 where more than one row of fins 52 form the heat sink device. Embodiment 50 is a nanotube array, (for example, carbon nanotubes) but many other materials could be employed for heat transfer. Also, if desired, structure 50 can be within a frame. This structure could stand alone, or could be imbedded in a plate fin device.

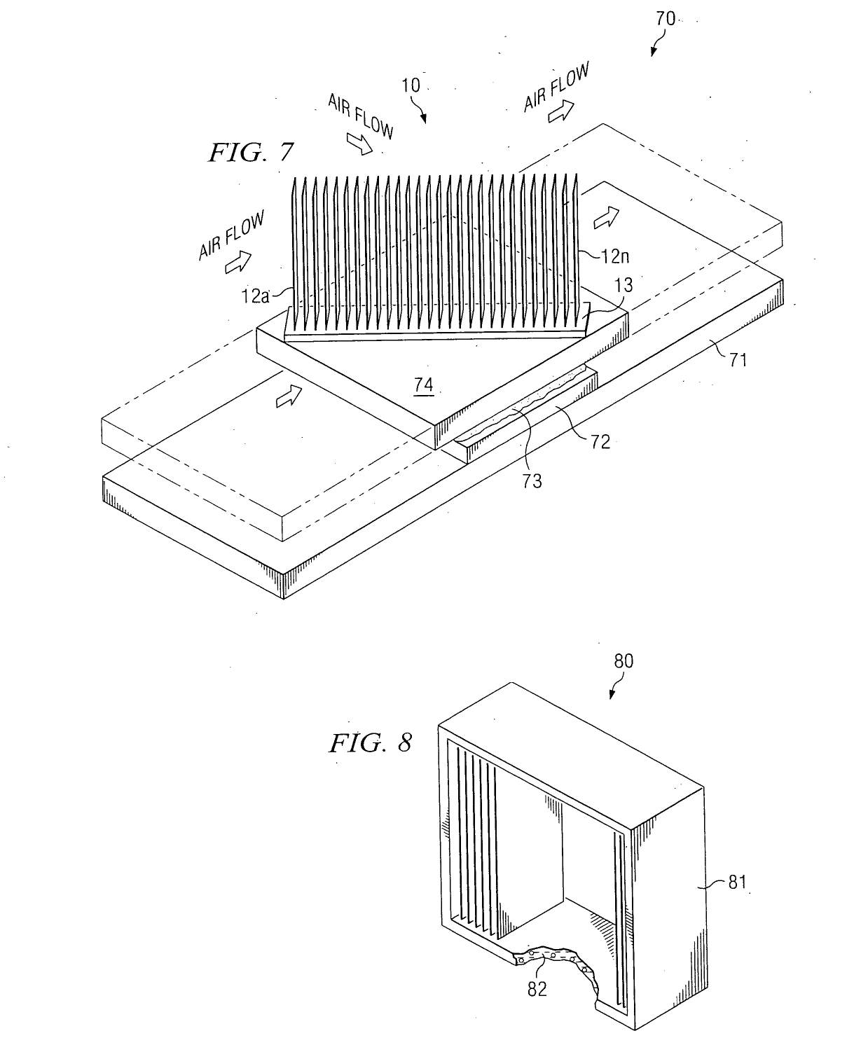

FIG. 6 illustrates embodiment 60 in which the cooling “fins” consist of mesh 601 woven from carbon nanotubes 62 (or other material) and webbing 61. Webbing 61 can be nanotubes, if desired. Of course, any combination of heat transfer materials can be used, all designed to provide an ultra dense heat sink. For example, carbon fibers, graphite, copper, aluminum, gold or diamond can be used. Also, foils in the range of one tenth of a millimeter can be used.

FIG. 7 illustrates one embodiment of heat sink transfer device 70 using at least one ultra-dense heat sink 10. Heat sink 10 (shown without its top frame support) is positioned angularly with respect to the air flow direction so as to be air flow direction made neutral. Base 13 of heat sink 10 is positioned on heat transfer plate 74 with thermal contact (bolted, soldered, brazed, etc.), which in turn is positioned to receive heat from electronic device 72. Note that base 13 could, if desired, be positioned to receive heat directly from electronic device 72 and thus could replace heat transfer plate 74. Or, alternatively, fins 12a-12n could be in continuous direct thermal contact with plate 74. Electronic device 72 is shown mounted to circuit board 71 in any well-known manner. If desired, thermal interface material 73 is positioned between plate 74 and electronic device 72 to facilitate heat transfer. Plate 74 is optional and its dimensions would be tailored to the size of the heat sinks used and their positioning. The phantom lines around plate 74 show a traditional size heat transfer plate, and the plate of this embodiment can be any dimension up to the phantom line. Using the embodiments discussed an omni-directional heat sink becomes available with a reduced weight.

FIG. 8 illustrates one embodiment 80 of a high density heat sink having heat pipe 81 built as part of the frame of the heat sink. The inside of heat pipe 81 is constructed with a wicking structure, such as structure 82, which serves to move liquid (or other heat transfer substances) around the frame of heat sink 80. The advantage of a heat pipe is that it has an effectively infinite thermal conductivity. Thus, it is possible to transfer heat from a device (not shown) at the bottom of the heat pipe to the top of the heat pipe with barely a temperature drop. Since the top surface would be at the same temperature as the base, the fin length is effectively cut in half, yielding even higher thermal efficiency by the uni-temperature nature of device 80.

Materials generally used in heat sink designs are aluminum and copper, but as discussed above, many other materials including carbon nanotubes, graphite, gold and diamond can be used to advantage.

It should be understood that the FIGURES herein are for illustrative purposes only and not drawn to scale.

1. A heat transfer device comprising:
at least one ultra-dense heat sink, and
means for maintaining said heat sink in a position to be air flow direction neutral.

2. The device of claim 1 wherein said maintaining means comprises:
at least one heat transfer plate.

3. The device of claim 1 wherein said heat transfer device has a footprint no larger than a device from which heat is to be transferred.

4. The device of claim 1 wherein said heat transfer device has a weight at least 50% lighter than a heat sink that is not ultra-dense.

5. The device of claim 1 wherein said maintaining means comprises:
positioning a plurality of said ultra-dense heat sinks around a common open space.

6. The device of claim 4 further comprising:
an air movement device positioned in conjunction with said common open space.

7. The device of claim 1 wherein said maintaining means comprises:
means for coupling said device to at least one electronic component.

8. The device of claim 6 wherein said coupling means comprises at least one heat transfer medium.

9. The device of claim 1 wherein said maintaining means comprises:
a plurality of individual ultra-dense heat sinks spaced apart from each other.

10. The device of claim 9 wherein at least some of said spaced apart heat sinks are at angles with respect to other of said heat sinks.

11. The device of claim 9 wherein at least some of said spaced apart heat sinks are at angles with respect to expected air flow motion.

12. A heat sink comprising:
a heat transfer plate for removing heat from an electronic circuit; and
at least one ultra-dense heat sink positioned on said heat transfer plate so as to be directionally neutral to air flow over said plate.

13. The heat sink of claim 12 wherein said directionally neutral positioning is such that certain of said heat sinks are positioned perpendicular to each other.

14. The heat sink of claim 12 wherein said directionally neutral positioning is such that certain of said heat sinks are positioned parallel to each other and angularly positioned with respect to anticipated air flow.

15. The heat sink of claim 12 wherein said ultra-dense heat sinks contain highly conductive fiber as part of their cooling structure.

16. The heat sink of claim 15 wherein said highly conductor fiber comprises carbon nanotubes.

17. The heat sink of claim 12 wherein said ultra-dense heat sinks contain mesh as part of their cooling structure.

18. The heat sink of claim 17 wherein said mesh comprises carbon nanotubes.

19. The heat sink of claim 12 wherein at least a portion of at least one of said ultra-dense heat sinks comprise a heat pipe.

20. A method of conducting heat away from an electronic device wherein said electronic device is constructed on a circuit board, said method comprising:
placing a plurality of heat transfer devices in heat transfer relationship with said electronic device; and
passing air through said heat transfer devices in at least one air flow direction.

21. The method of claim 20 wherein said air may flow in any direction with respect to the orientation of said plurality of heat transfer devices.

22. The method of claim 21 wherein said placing comprises:
aligning at least some of said heat transfer devices at angles to any said air flow direction.
